(19) United States
(12) Patent Application Publication
(10) Pub. No.: US 2004/0188789 A1
(43) Pub. Date: Sep. 30, 2004

(54) Semiconductor device and method for machining a semiconductor substrate

(75) Inventors: Tohru Koyama, Tokyo (JP); Takeshi Yoshida, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/684,507

(22) Filed: Oct. 15, 2003

(30) Foreign Application Priority Data
Mar. 31, 2003 (JP) P2003-094542

(51) Int. Cl. H01L 23/58; H01L 23/48; H01L 29/40; H01L 33/00; H01L 21/301; H01L 21/46; H01L 21/00

(52) U.S. Cl. 257/432; 257/98; 438/460; 438/462; 257/618; 438/29

(57) ABSTRACT

A recessed portion 4 is formed on a main surface 3a of a semiconductor substrate 1 of a semiconductor device 10. A convex portion 5 with a partial spherical surface, functioning as solid immersion lens, is formed on a bottom surface of the recessed portion 4. An angle θ1 formed between a side surface 4b of the recessed portion 4 and the main surface 3a of the semiconductor substrate 1 is larger than 90°. This makes it possible to reduce an amount of an analysis light 20 interrupted by the semiconductor substrate 1 when analysis light 20 is used in reverse surface analysis of the semiconductor device 10. Accordingly, the distance between the surface of the convex portion 5 and the side surface 4b of the recessed portion 4 can be reduced, and the time required for machining the semiconductor substrate can be reduced.

### BACKGROUND OF THE INVENTION

1. Field of the Invention

This invention relates to a substrate structure preferably applicable to analysis of a semiconductor device performed with an optical means, and also relates to a method for forming the above substrate structure.

2. Description of the Background Art

The multilayered wiring structure is conventionally adopted to LSI or other semiconductor devices. However, the multilayered wiring structure makes it difficult to perform evaluation and analysis from the upper surface of a semiconductor substrate. Thus, approach to the semiconductor substrate is limited to the reverse surface of the semiconductor substrate. One of main fault analyses performed from the reverse surface of a semiconductor substrate is emission analysis which performs the fault analysis by detecting very weak light emitting from a current leak position. Another one of the main fault analyses is OBIC (Optical Beam Induced Current) or OBIRCH (Optical Beam Induced Resistance CHange) method which identifies a fault location based on an image converted from the change of induced current or power source current generated in response to irradiation of a laser beam. Another one of the main fault analyses is laser voltage probe (LVP) which monitors an electric potential waveform at an arbitrary portion by detecting strength or phase change of reflected light of an irradiated laser beam. According to this kind of analyses performed from the reverse surfaces of semiconductor substrates (hereinafter, simply referred to as “reverse surface analysis”), it is necessary to access semiconductor elements formed on an upper surface of each semiconductor substrate through a substrate body having the thickness of several hundreds μm. To this end, an infrared having the capability of penetrating the silicon is usually utilized. However, the wavelength of the infrared to be used is not smaller than 1 μm. Its effective spatial resolution is not smaller than 0.7 μm. In this respect, adopting the reverse surface analysis will significantly sacrifice the image resolution.

Hence, as a technique for improving the spatial resolution, S.B. Ippolito et al., “High spatial resolution subsurface microscopy”, Applied Physics Letters, Vol.78, No.26, June 2001, pp. 4071-4073 (hereinafter, referred to as non-patent document 1) proposes a technique using a silicon-made solid immersion lens which may be hereinafter referred to as ‘SIL’. This technique is based on increase of the refractive index of an optical medium for obtaining an excellent resolution exceeding a diffraction limit which is usually dependent on the wavelength of the light.

According to the technique disclosed in the above non-patent document 1, a hemispherical SIL is hermetically adhered on the reverse surface of a semiconductor substrate. The silicon-permeable light is entered via this SIL into the semiconductor substrate. Using such an SIL brings the effect of greatly increasing a converging angle compared with a case where no SIL is used. The resolution d is expressed by using a formula d=λ/(2·n·sin θ). Using the SIL makes it possible to improve a numerical aperture NA, expressed by n·sin θ, to a level multiplied by the square of the refractive index n in an ideal case. In the above formula, θ represents the half angle of the converging angle and λ represents the wavelength of the light.

However, according to the technique disclosed in the non-patent document 1, the resolution will greatly decrease if there is any clearance between the semiconductor substrate and the SIL. To solve this problem, Japanese Patent Application Laid-open No. 2002-189000 (hereinafter, referred to as patent document 1) discloses a technique for machining a semiconductor substrate by using a grinding tool having a groove configured into a semicircular shape in cross section. By using this grinding tool, a hemispherical convex portion is formed on the surface of the semiconductor substrate, and the convex portion can be used as an SIL. As a result, it becomes possible to integrally form the SIL and the semiconductor substrate.

According to the technique disclosed in the above patent document 1, it is substantially impossible to provide a clearance between the SIL and the semiconductor substrate because the convex portion functioning as SIL is integrally formed with the semiconductor substrate. Thus, the resolution can be improved compared with the technique disclosed in the non-patent document 1.

Another technique using the SIL for the reverse surface analysis of a semiconductor device is disclosed in Terada, “Effectiveness of Solid Immersion Lens”, the 14th semiconductor workshop lecture papers, sponsored by Hamamatsu Photonics, or in Yoshida et al, “Quality Improvement in Laser Voltage Probe (LVP) Analysis”, LSI testing symposium/2002, introductory paper articles, pp.143-148. Furthermore, a technique relating to the above patent document 1 is disclosed in an earlier patent application (not published yet) filed by this applicant and currently pending as Japanese Patent Application No. 2003-5550.

According to the technique disclosed in the above patent document 1, the reverse surface of a semiconductor substrate is machined by using the grinding tool to form the SIL. An angle between a machined side surface formed by this machining process and the reverse surface of the semiconductor substrate is 90° (refer to FIGS. 1 and 2 of the patent document 1). Accordingly, it is necessary to secure a sufficient distance between the convex portion functioning as SIL and the machined side surface to prevent the semiconductor substrate from interrupting the light irradiated through an objective lens during the reverse surface analysis of a semiconductor device or the light taken out toward the objective lens from the semiconductor device during the reverse surface analysis. Accordingly, a cut amount of the semiconductor substrate to be removed though the machining operation was large. And, a relatively long time was required to accomplish the machining operation.

Furthermore, the grinding tool disclosed in the above patent document 1 has a large area contacting with a machined surface. Therefore, it was difficult to assure sufficient accuracy in machining the convex portion.

### SUMMARY OF THE INVENTION

It is a first object of the present invention to provide a technique capable of reducing the time required for machining a semiconductor substrate. It is a second object of the present invention to provide a technique capable of improving the accuracy in machining a solid immersion lens.

The present invention provides a semiconductor device including a semiconductor substrate having a first main surface and a second main surface opposite to said first main surface, and a semiconductor element formed on the first main surface of the semiconductor substrate. A recessed portion is provided on the second main surface of the semiconductor substrate. A convex portion functioning as a solid immersion lens and having a partial spherical surface is provided on a bottom surface of the recessed portion. And, an angle θ1 formed between a side surface of the recessed portion and the second main surface is larger than 90°.

As the angle between the side surface of the recessed portion and the second main surface of the semiconductor substrate is set to be a value larger than 90°, it becomes possible to reduce the amount of light, such as the incident light into the convex portion, or the radiant light or reflected light from the semiconductor device, interrupted by the semiconductor substrate during the analysis of the semiconductor device using an optical means. Accordingly, the distance between the surface of the convex portion and the side surface of the recessed portion can be reduced, and the time required for machining the substrate can be reduced.

Futhermore, the present invention provides a method for machining a semiconductor substrate including steps (a) and (b). The step (a) is a step of preparing a semiconductor substrate. The step (b) is a step of machining the semiconductor substrate from its main surface by using a single point tool to form a convex portion functioning as a solid immersion lens and having a partial spherical surface. A first angle formed between a machined side surface resulting from the machining operation applied to the semiconductor substrate in the step (b) and the main surface of the semiconductor substrate is larger than 90°. A cutting part of the single point tool has a tip and a cutting edge. The cutting edge extends from the tip with a predetermined length so as to form a second angle between a central axis of the single point tool and the cutting edge. And, the second angle is equal to a value obtained by subtracting 90° from the first angle.

As the semiconductor substrate is machined by using the cutting edge having the angle corresponding to the angle between the machined side surface and the main surface of the semiconductor substrate, it becomes possible to easily form a semiconductor substrate with the angle being larger than 90° between the machined side surface and the main surface of the semiconductor substrate. Furthermore, using the single point tool for machining the semiconductor substrate makes it possible to reduce the contact area between the machining means and the machined surface. Therefore, accuracy in machining the convex portion functioning as a solid immersion lens can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are views showing the structure of a semiconductor device in accordance with a first embodiment of the present invention;

FIG. 2 is a cross-sectional view showing the structure of the semiconductor device in accordance with the first embodiment of the present invention;

FIG. 3 is a cross-sectional view showing the structure of the semiconductor device in accordance with the first embodiment of the present invention;

FIG. 4 is a cross-sectional view, showing the structure of a semiconductor device in accordance with a second embodiment of the present invention;

FIG. 5 is a cross-sectional view showing the machining method of a semiconductor substrate in accordance with a third embodiment of the present invention;

FIG. 6 is a side view showing the structure of a single point tool used in the manufacturing method of the semiconductor device in accordance with the third embodiment of the present invention; and

FIG. 7 is a cross-sectional view showing the machining method of a semiconductor device in accordance with a fourth embodiment of the present invention.

### DESCRIPTION OF THE PREFERRED EMBODIMENTS

### First Embodiment

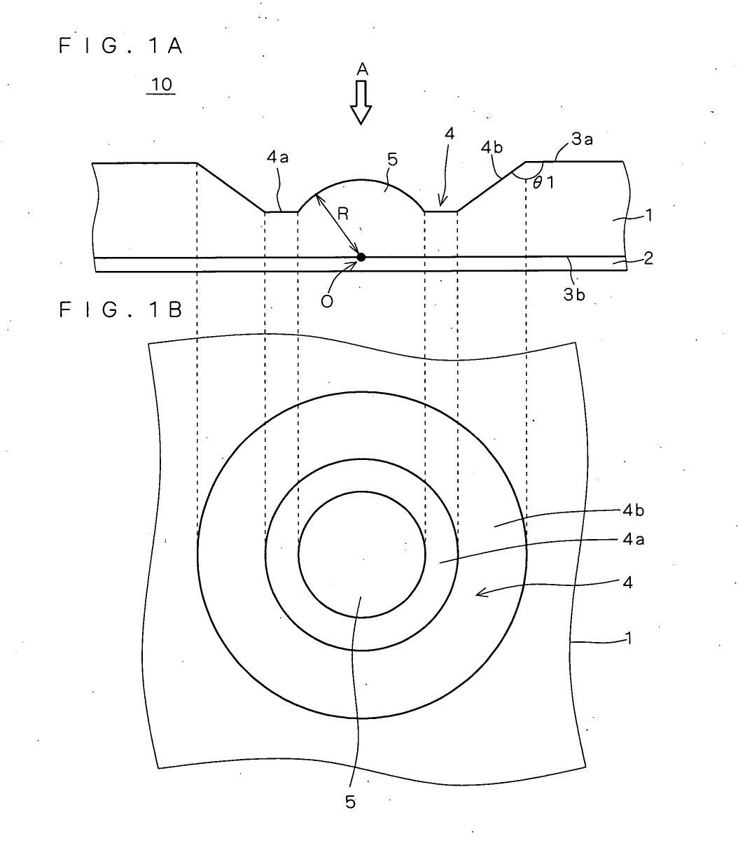

FIGS. 1A and 1B are views showing the structure of a semiconductor device 10 in accordance with a first embodiment of the present invention. FIG. 1A is a cross-sectional view showing the structure of the semiconductor device 10. FIG. 1B is a plane view showing the structure of the semiconductor device 10 seen from the direction of an arrow A of FIG. 1A.

As shown in FIGS. 1A and 1B, a semiconductor substrate 1 has a main surface 3a at one side. A recessed portion 4 is formed on the main surface 3a. A convex portion 5 is formed on a bottom surface 4a of the recessed portion 4. The recessed portion 4 and the convex portion 5 are integrally formed by machining the semiconductor substrate 1 from its main surface 3a. For example, the semiconductor substrate 1 is a silicon substrate with a thickness dw of, for example, 400 μm.

The convex portion 5, functioning as a hemisphere-type SIL, has a surface configured into a partial spherical surface. A radius R of the partial spherical surface is for example 300 μm. A center O of the partial spherical surface is positioned on the main surface 3b of the semiconductor substrate 1 opposite to the main surface 3a. Furthermore, an angle θ1 is formed between a side surface 4b of the recessed portion 4 and the main surface 3a of the semiconductor substrate 1 where the recessed portion 4 is not provided. The side surface 4b of the recessed portion 4 is a machined side surface resulting from the machining operation applied to the main surface 3a of the semiconductor substrate 1 to form the convex portion 5 and the recessed portion 4. Hereinafter, the side surface 4b may be referred to as machined side surface 4b.

A device forming layer 2 is provided on the main surface 3b of the semiconductor substrate 1. Although not shown in the drawing, MOS transistors or other semiconductor elements, interlayer insulating films, contact plugs, and the wiring are formed in the device forming layer 2.

The convex portion 5, having the above-described configuration, functions as a spherical lens, and is utilized as SIL in carrying out the reverse surface analysis for the semiconductor elements or the like formed in the device forming layer 2. For example, according to the emission analysis, the light emitting from a current leak position of a semiconductor element passes the convex portion 5 and exits out of the semiconductor substrate 1. The fault analysis is performed by utilizing the light taken out in this manner. Furthermore, according to the OBIC, the laser beam is irradiated onto a semiconductor element via the convex portion 5. The fault analysis is performed by utilizing the change of induced current generated in response to irradiation of the laser beam.

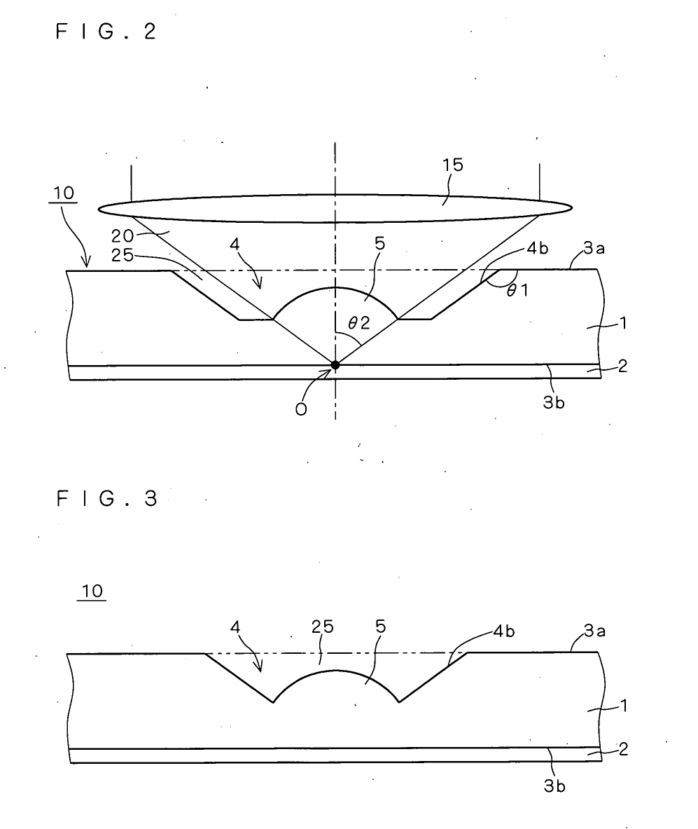

Next, the angle θ1 formed between the side surface 4b of the recessed portion 4 and the main surface 3a of the semiconductor substrate 1 will be explained in more detail with reference to FIG. 2.

When the reverse surface analysis is performed for the semiconductor device 10 by utilizing the convex portion 5 as SIL under an optical means, an objective lens 15 is provided at the same side as the main surface 3a of the semiconductor substrate 1 with a predetermined distance from the semiconductor substrate 1, as shown in FIG. 2. The incident light 20, condensed by the objective lens 15, passes the convex portion 5 and irradiates the device forming layer 2. The radiant light 20 emitted from the device forming layer 2 or the reflected light 20 reflected from the device forming layer 2 passes the convex portion 5 and enters into the objective lens 15. The incident light 20, the radiant light 20, and the reflected light 20 relevant to the reverse surface analysis may be collectively referred to as “analysis light 20” in the following description.

According to the first embodiment of the present invention, the angle θ1 formed between the side surface 4b of the recessed portion 4 and the main surface 3a of the semiconductor substrate 1 is equal to or larger than an angle obtained by adding 90° to a half angle θ2 of the converging angle of the objective lens 15. In other words, the angle θ1 satisfies the following formula (1).

θ1≧90°+θ2 (1)

The half angle θ2 of the converging angle of the objective lens 15 is approximately 30° when the numerical aperture is 0.5.

According to the semiconductor device 10 having the convex portion 5 functioning as hemisphere-type SIL as disclosed in the first embodiment, the center O of the partial spherical surface of the convex portion 5 and a focal point (aplanatic point) in the semiconductor device 10 are located at the same position. In other words, according to the first embodiment, the focal point is positioned on the main surface 3b of the semiconductor substrate 1. Accordingly, as shown in FIG. 2, the incident light 20 incoming from the objective lens 15 and the radiant light 20 or the reflected light 20 outgoing from the focal point can advance straight without refracting at the surface of the convex portion 5. Therefore, setting the angle θ1 between the side surface 4b of the recessed portion 4 and the main surface 3a of the semiconductor substrate 1 to a value equal to or larger than (90°+θ2) according to the first embodiment makes it possible to surely prevent the analysis light 20 from being interrupted by the semiconductor substrate 1. Hence, the distance between the surface of the convex portion 5 and the side surface 4b of the recessed portion 4 can be reduced. A machined region 25 to be removed from the semiconductor substrate 1 in forming the convex portion 5 and the recessed portion 4 can be reduced. In FIG. 2, an alternate long and two short dashes line represents the original position of the main surface 3a of the semiconductor substrate 1 before the machining processing is performed.

In this manner, even when a hemisphere-type SIL is formed on the main surface 3a of the semiconductor substrate 1, providing the angle θ1 equal to or larger than (90°+θ2) between the machined side surface 4b and the main surface 3a of the semiconductor substrate 1 does not sacrifice the optical characteristics of the SIL and makes it possible to reduce the machined amount of the semiconductor substrate 1 compared with the technique disclosed in the above patent document 1. Accordingly, the time required for machining the semiconductor substrate can be reduced.

In a case that the machined region 25 is minimized, the side surface 4b of the recessed portion 4 is continuous with the partial spherical surface of the convex portion 5 as shown in FIG. 3. In this case, the time required for machining the semiconductor substrate can be minimized without deteriorating the SIL performance.

As described above, to surely prevent the semiconductor substrate 1 from interrupting the analysis light 20, the first embodiment forms the angle θ1 being equal to or larger than (90°+θ2) between the side surface 4b of the recessed portion 4 and the main surface 3a of the semiconductor substrate 1. However, as far as the angle θ1 is larger than 90°, the amount of the analysis light 20 interrupted by the semiconductor substrate 1 can be reduced substantially compared with the technique disclosed in the above patent document 1 according to which the corresponding angle θ1 is set to 90°. Hence, even in this case, the distance between the convex portion 5 and the side surface 4b of the recessed portion 4 can be reduced and the time required for machining a conductor substrate can be reduced.

### Second Embodiment

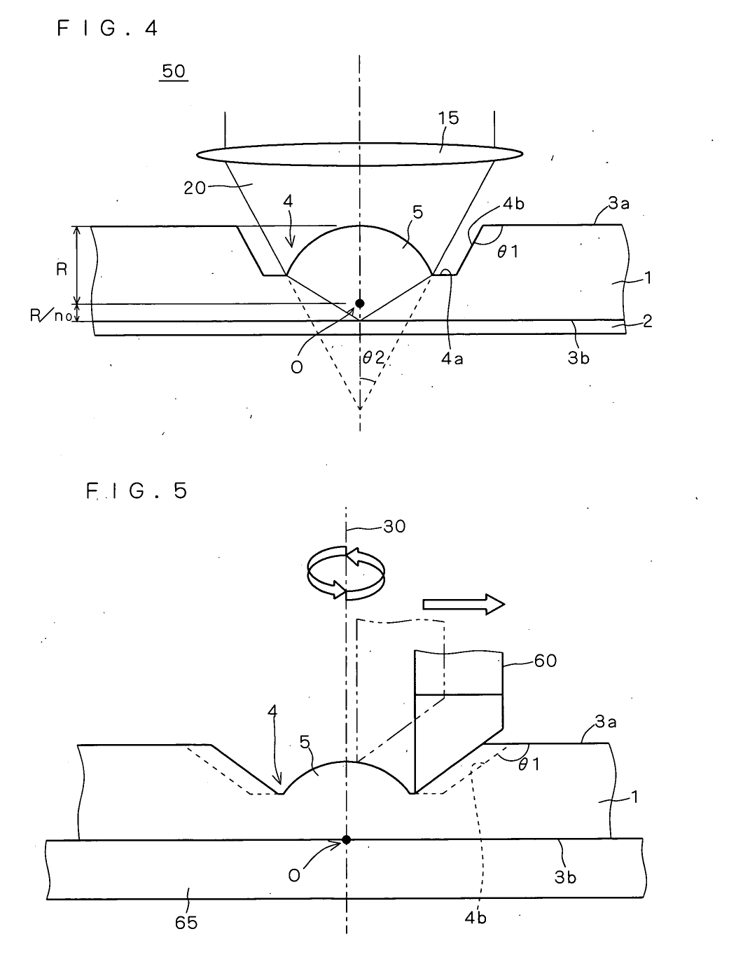

FIG. 4 is a cross-sectional view showing the structure of a semiconductor device 50 in accordance with a second embodiment of the present invention. The semiconductor device 50 in accordance with the second embodiment differs from the above-described semiconductor device 10 in that the convex portion 5 functioning as hemisphere-type SIL is replaced with a convex portion 5 functioning as super-sphere-type SIL. Furthermore, the angle θ1 formed between the side surface 4b of the recessed portion 4 and the main surface 3a of the semiconductor substrate 1 is different from the angle θ1 of the above-described semiconductor device 10 and is set to be equal to or larger than 106°. The reasons why the angle θ1 is set to the above value will be explained hereinafter.

According to the semiconductor device 50 having the convex portion 5 functioning as super-sphere-type SIL, the center O of the partial spherical surface of the convex portion 5 and the focal point in the semiconductor device 50 are located at different positions. More specifically, when no represents the refractive index of the semiconductor substrate 1, the center O of the partial spherical surface of the convex portion 5 is offset inward in the depth direction from the main surface 3b of the semiconductor substrate 1 with a distance of R/n₀. The focal point is positioned on the main surface 3b of the semiconductor substrate 1. Accordingly, as shown in FIG. 4, the analysis light 20 refracts on the surface of the convex portion 5.

In the case that the reverse surface analysis is performed on the semiconductor substrate 1 having no SIL, the numerical aperture NA is expressed by NA=n·sin θ2. In this formula, n represents the refractive index of a medium intervening between the objective lens 15 and the semiconductor substrate 1. When the super-sphere-type SIL is formed on the main surface 3a of the semiconductor substrate 1 according to the second embodiment, the refractive index n and sin θ2 are both multiplied by n₀. As a result, compared with the case of using no super-sphere-type SIL, the numerical aperture NA becomes a value multiplied by the square of n₀. The maximum value of the numerical aperture NA is n₀. Accordingly, when the numerical aperture NA is maximized, namely in the case that the numerical aperture NA=n₀, the following formula (2) is satisfied.

n₀=(n×n₀)×(sin θ2×n₀) (2)

In general, the reverse surface analysis is carried out in the air. Accordingly, n=1. The above formula (2) is rewritten into the following formula (3).

n₀=n₀×n₀·sin θ2 (3)

From the above formula (3), the half angle θ2 of the converging angle of the objective lens 15 in the case that the numerical aperture NA is maximized satisfies the following formula (4).

$$θ 2 = {sin}^{- 1} ( \frac{1}{{n}_{0}} ) \qquad ( 4 )$$

In this case, the wavelength permeable in the silicon is not smaller than 1 μm. When the semiconductor substrate 1 is a silicon substrate, the wavelength of the analysis light 20 is not smaller than 1 μm. When the wavelength is 1 μm, the refractive index of the silicon is 3.6. Entering this value as no into the formula (4) derives θ2≈16°. Accordingly, enabling the light having the angle not smaller than this value to enter or radiate or reflect makes it possible to prevent the analysis light 20 having the wavelength of at least 1 μm from being interrupted by the semiconductor substrate 1. Hence, according to the second embodiment, the angle formed between the side surface 4b of the recessed portion 4 and the main surface 3a of the semiconductor substrate 1 is set to be equal to or larger than (90°+16°)=106°. With this setting, the amount of the analysis light 20 interrupted by the semiconductor substrate 1 can be reduced.

As described above, setting the angle θ1 between the machined side surface 4b and the main surface 3a of the semiconductor substrate 1 to be equal to or larger than 106° can reduce the possibility that the semiconductor substrate 1 interrupts the analysis light 20. Hence, the distance between the surface of the convex portion 5 and the side surface 4b of the recessed portion 4 can be reduced. The machined region to be removed from the semiconductor substrate 1 in forming the convex portion 5 and the recessed portion 4 can be reduced. Accordingly, even in the case that the super-sphere-type SIL is formed on the main surface 3a of the semiconductor substrate 1, the second embodiment does not sacrifice the optical characteristics of the SIL and makes it possible to reduce the time required for machining the semiconductor substrate compared with the technique disclosed in the above patent document 1. The time required for machining the semiconductor substrate is minimized when the partial spherical surface of the convex portion 5 is continuous with the machined side surface 4b because the distance between the convex portion 5 and the side surface 4b is minimized.

### Third Embodiment

FIG. 5 is a cross-sectional view showing the machining method of a semiconductor substrate in accordance with a third embodiment of the present invention. The machining method in accordance with the third embodiment is a substrate machining method used for forming the semiconductor substrate 1 of the above-described semiconductor device 10 or 50. Hereinafter, the machining method in accordance with the third embodiment will be explained with reference to FIG. 5. Although FIG. 5 shows the semiconductor substrate 1 of the semiconductor device 10, the semiconductor substrate 1 of the semiconductor device 50 according to the second embodiment can be also formed by using the following method.

As shown in FIG. 5, the semiconductor substrate 1 to be machined is fixed on a rotatable stage 65 by means of a resin or the like (not shown). Then, the stage 65 is rotated. In response to the rotation of the stage 65, the semiconductor substrate 1 rotates about an axis 30 serving as a rotational axis. The rotational axis 30 passes the center O of the partial spherical surface of the convex portion 5 and extends in the thickness direction of the semiconductor substrate 1. Then, under the condition that the semiconductor substrate 1 is rotating, a single point tool 60 attached to a lathe (not shown) is applied to the main surface 3a of the semiconductor substrate 1 to form the recessed portion 4 and the convex portion 5.

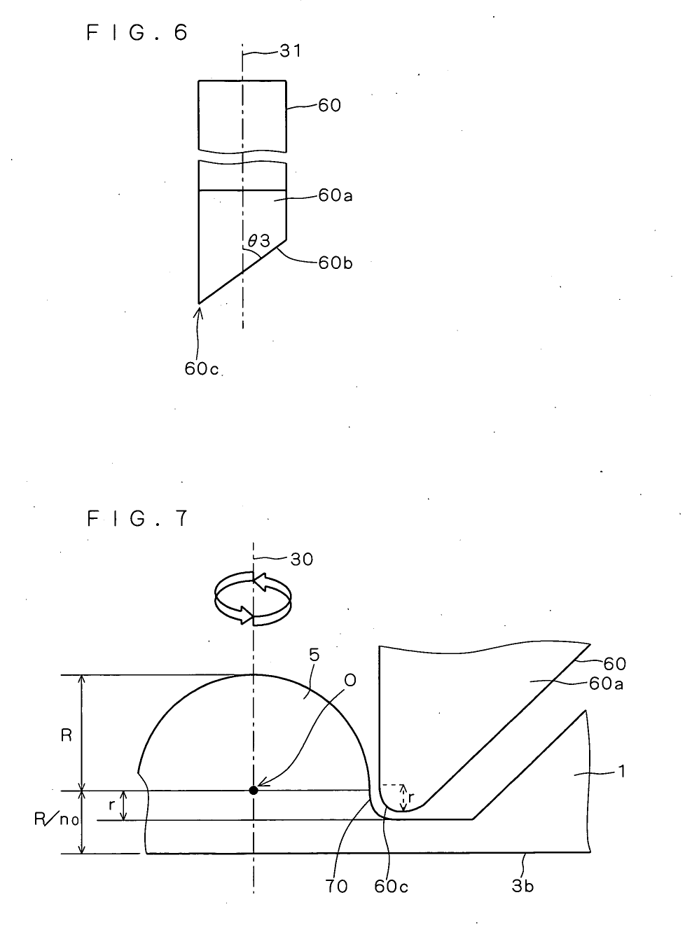

FIG. 6 is a side view showing the structure of the single point tool 60. As shown in FIG. 6, a cutting part 60a of the single point tool 60 has a tip 60c and a cutting edge 60b. The cutting edge 60b extends from the tip 60c with a predetermined length so as to form an angle θ3 between a central axis 31 extending in the longitudinal direction of the single point tool 60 and the cutting edge 60b. The angle θ3 is equal to a value obtained by subtracting 90° from the angle θ1 formed between the machined side surface 4b and the main surface 3a of the semiconductor substrate 1. The length of the cutting edge 60b is set to be longer than a cross-sectional length of the machined side surface 4b in the thickness direction of the semiconductor substrate 1. The cutting part 60a of the single point tool 60 is made of, for example, diamond.

According to the third embodiment of the present invention, in the machining operation of the semiconductor substrate 1, the semiconductor substrate 1 is cut by bringing the tip 60c and the cutting edge 60b of the cutting part 60a of the single point tool 60 into contact with the semiconductor substrate 1, so that the recessed portion 4 and the convex portion 5 functioning as SIL are formed on the main surface 3a of the semiconductor substrate 1. During the machining operation of the semiconductor substrate 1, the central axis 31 of the single point tool 60 is maintained in parallel with the rotational axis 30 of the semiconductor substrate 1. The single point tool 60 shifts in the direction perpendicular to the thickness direction of the semiconductor substrate 1. The position of the single point tool 60 in the thickness direction of the semiconductor substrate 1 is controlled by the lathe according to the configuration of the recessed portion 4 and the convex portion 5.

As described above, according to the machining method of the semiconductor substrate in accordance with the third embodiment, the cutting edge 60b used to cut the semiconductor substrate 1 has the angle θ3 determined in relation to the angle θ1 formed between the machined side surface 4b and the main surface 3a of the semiconductor substrate 1. Therefore, the semiconductor substrate 1 shown in FIGS. 1A and 1B or the semiconductor substrate 1 shown in FIG. 4 can be easily realized.

Furthermore, as described above, the third embodiment is characterized by using both the tip 60c and the cutting edge 60b of the cutting part 60a of the single point tool 60 to machine the semiconductor substrate 1. This makes it possible to reduce the contact area between the machining means and the machined surface compared with the machining method disclosed in the above patent document 1. Accordingly, the accuracy in machining the convex portion 5 can be improved. The SIL performance of the convex portion 5 can be improved.

### Fourth Embodiment

Depending on the performance of the used objective lens 15, a hemispherical surface may be formed on the surface of the convex portion 5 functioning as super-sphere-type SIL shown in FIG. 4.

On the other hand, as shown in FIG. 7, in the case that the convex portion 5 is formed by placing the tip of the above-described single point tool 60 on the semiconductor substrate 1, a skirt portion 70 is formed on the edge portion of the surface of the convex portion 5. The radius of the skirt portion 70 in the cross section taken along the thickness direction of the semiconductor substrate 1 (hereinafter, referred to as “skirt radius”) is substantially equal to the radius r of the tip 60c of the cutting part 60a of the single point tool 60 (hereinafter, simply referred to as “tip radius r of cutting part 60a”). The skirt portion having been thus formed does not function as SIL. Accordingly, to form the hemispherical surface on the surface of convex portion 5 as described above, it is necessary to further machine the semiconductor substrate 1 deeply by the amount of distance r from the center O of the partial spherical surface of the convex portion 5.

In the case of forming the convex portion 5 functioning as super-sphere-type SIL, the distance from the center O of the partial spherical surface of the convex portion 5 to the main surface 3b of the semiconductor substrate 1 is set to be R/n₀. Accordingly, to form the hemispherical surface on the surface of the convex portion 5, the tip radius r of the cutting part 60a needs to satisfy the following formula (5).

r<R/n₀ (5)

Furthermore, the radius R of the partial spherical surface of the convex portion 5 is maximized when the following formula (6) is satisfied.

dw=R(1+1/n₀) (6)

In the above formula (6), dw represents the thickness of the semiconductor substrate 1. Accordingly, the maximum value of the radius R is expressed by R=dw/(1+1/n₀). Entering this R into the above formula (5) derives the following formula (7).

r<dw/(n₀+1) (7)

In the case that the semiconductor substrate 1 is a silicon substrate, the minimum wavelength of the light penetrating the semiconductor substrate 1 becomes 1 μm. When the wavelength is 1 μm, the refractive index of the silicon is 3.6. Entering this value as no into the formula (7) derives the following formula.

r<0.22×dw (8)

According to the fourth embodiment of the present invention, as shown in the above formula (8), the tip radius r of the cutting part 60a of the single point tool 60 is set to be less than 22% of the thickness dw of the semiconductor substrate 1. By using the single point tool 60 having the tip radius r being set in this manner, the convex portion 5 functioning as the super-sphere-type SIL is formed. This makes it possible to easily form a hemispherical surface on the surface of the convex portion 5. Accordingly, even in the case that a hemispherical SIL is formed on the semiconductor substrate 1 depending on the performance of the objective lens 15 used in the reverse surface analysis, such an SIL can be easily formed by using the above-described single point tool 60.

While the invention has been shown and described in detail, the foregoing description is in all aspects illustrative and not restrictive. It is therefore understood that numerous other modifications and variations can be devised without departing from the scope of the invention.

What is claimed is:

1. A semiconductor device comprising:
a semiconductor substrate having a first main surface and a second main surface opposite to said first main surface; and
a semiconductor element formed on said first main surface of said semiconductor substrate,
wherein a recessed portion is provided on said second main surface of said semiconductor substrate;
a convex portion functioning as a solid immersion lens and having a partial spherical surface is provided on a bottom surface of said recessed portion; and
an angle θ1 formed between a side surface of said recessed portion and said second main surface is larger than 90°.

2. The semiconductor device according to claim 1, wherein said angle 01 satisfies the following relationship
θ1≧90°+θ2
where θ2 represents a half angle of a converging angle of an objective lens provided at the same side as said second main surface with a predetermined distance from said semiconductor substrate when said semiconductor device is analyzed by utilizing said convex portion as the solid immersion lens under a given optical means.

3. The semiconductor device according to claim 1, wherein said angle θ1 is equal to or larger than 106°.

4. A method for machining a semiconductor substrate comprising the steps of:
(a) preparing a semiconductor substrate; and
(b) machining said semiconductor substrate from its main surface by using a single point tool to form a convex portion functioning as a solid immersion lens and having a partial spherical surface,
wherein a first angle formed between a machined side surface resulting from the machining operation applied to said semiconductor substrate in said step (b) and said main surface of said semiconductor substrate is larger than 90°,
a cutting part of said single point tool has a tip and a cutting edge, said cutting edge extending from said tip with a predetermined length so as to form a second angle between a central axis of said single point tool and said cutting edge, and
said second angle is equal to a value obtained by subtracting 90° from said first angle.

5. The method for machining a semiconductor substrate according to claim 4, wherein a tip radius of said cutting part of said single point tool is less than 22% of a thickness of said semiconductor substrate.
